(19) United States
(12) Patent Application Publication
(10) Pub. No.: US 2003/0212999 A1
(43) Pub. Date: Nov. 13, 2003

(54) System and method for providing video telephony over a cable access network infrastructure

(76) Inventor: Simin Cai, Basking Ridge, NJ (US)

Correspondence Address: PAUL, HASTINGS, JANOFSKY & WALKER LLP, P.O. BOX 919092, SAN DIEGO, CA, 92191-9092, US

(21) Appl. No.: 10/434,865

(22) Filed: May 8, 2003

Related U.S. Application Data
(60) Provisional application No. 60/378,355, filed on May 8, 2002.

(51) Int. Cl. H04N 7/173; H04N 7/12; H04L 1/00; H04J 1/16; H04J 3/14; G06F 11/00; H04L 12/26; G08C 15/00; G01R 31/08; H04L 12/28; H04L 12/66; H04N 11/02; H04N 11/04

(52) U.S. Cl. 725/119; 348/384.1; 725/122; 725/118; 370/230; 370/351; 370/355

(57) ABSTRACT

Video telephony is implemented via a set-top box located at each participating party's site, a number of media gateways located at one or more cable TV distribution hubs or headends, and a number of software switches located at one or more headends and/or within the Internet or a managed data network. The set-top box provides an interface for a participating party to send and receive voice, video, and data converged transmissions. The media gateway is designed to handle both in-band (media) and out-of-band (call signaling) transmissions, and comprises a switching core that directs the out-of-band transmissions to the software switch. The software switch manages all out-of-band signaling and controls the operation of the media gateway.

### BACKGROUND

1. Field of Invention

The present invention relates to communications over a cable television infrastructure, and more particularly, to providing video telephony over a hybrid fiber coax (HFC) cable access network.

2. Description of Related Art

The demand for data services by subscribers is continually increasing. Current data delivery technologies include digital subscriber line (DSL) technologies, which use telephony technology, cable modem systems using television technology and hybrid fiber coax (HFC) distribution networks, fixed wireless communications, 2-way satellite communications, etc. Unfortunately, these conventional technologies generally only enable a single service to operate in real-time, rather than combining multiple services together seamlessly to offer integrated services. For example, in a Voice-over-Internet Protocol (VoIP) infrastructure, telephone services are implemented via Internet Protocol (IP), but video telephony, e.g., videoconferencing and web-casting service for real-time presentations and panel discussions, exceeds the capabilities and bandwidth limitations of conventional VoIP technology.

Data over cable service interface specification (DOCSIS) is a cable modem standard that defines hardware and systems compatibility, along with automated configuration and management, to allow cable modems and cable modem termination systems (CMTS) from different vendors to operate on the same network using the common DOCSIS standards and protocols. The International Telecommunications Union (ITU) incorporates DOCSIS in their cable modem standard ITU J.112, which is incorporated herein by reference in its entirety.

In a typical cable modem system, delivery of analog television downstream to the subscriber occupies the spectrum between approximately 54 MHz to 550 MHz, which leaves a relatively small range of spectrum for the delivery of digital information over HFC cable modem systems. To deliver DOCSIS data services over a cable television network, one 6 MHz radio frequency (RF) channel in the 550-860 MHz spectrum range is typically allocated for downstream traffic to homes and another channel, usually smaller such as 3.2 MHz or less, in the 5-42 MHz band is used to carry upstream signals. Therefore, two common delivery frequency ranges for a conventional consumer-based HFC system are those between approximately 15-42 MHz (upstream) and those between approximately 550-860 MHz (downstream).

A CMTS at a cable headend communicates through these channels with cable modems located at a subscriber's premise. Typically, the downstream channels support both 64 and 256 quadrature amplitude modulation (QAM) schemes. Generally, the downstream channels use ITU J.83-B, which is another ITU standard, variable-depth interleaving, and Reed-Solomon forward error correction. The basic structure of the network is IP over Ethernet. Once the transmission protocols have been established, the network operates transparently as an Ethernet network using the above-mentioned standards listed above, as well as many others, to ensure connectivity and interoperability with other networks and data products. These legacy systems broadcast all data to every downstream subscriber using a shared frequency channel. For a 6 MHz channel, the total data bandwidth is approximately 27-38 megabits per second (Mbps) for digital information. But because the channel is shared among many subscribers, the data rate for any one subscriber varies dramatically depending upon the time of use and the number of subscribers simultaneously logged on. Moreover, the quality of service (QoS) is particularly low during popular usage time periods. A typical legacy system might distribute the shared channel among 4 separate nodes, each serving approximately 500 subscribers or more, so that the resulting downstream data rate is relatively low. The upstream performance is often no better, and is sometimes worse, than a standard 56 Kbps modem, which doesn't provide, for example, a high enough baud rate for adequate bilateral video communications.

Advances in digital broadcasting are now enabling cable television providers and multiple service operators (MSO) to offer interactive services, such as video-on-demand (VOD), enhanced pay-per-view (EPPV), and streaming video in addition to receiving television channels and Internet access. Conventional interactive cable television systems, however, are limited to unidirectional video communication and/or audio telephony, and do not support video telephony.

By using a digital network, out-of-band signaling for telephony is possible as well as video and audio transmission in both the upstream and downstream directions. A conventional cable headend includes a processor for calculating and generating a randomized back-off array for each of a plurality of subscriber digital video home terminals. Each subscriber digital video home terminal receives the randomized back-off array for controlling, through an algorithm, when a digital video home terminal attempts to send a message to a cable headend. Such a conventional system still suffers from QoS problems, especially with end-to-end QoS, when the policy control that is required for audio/video telephony is included.

### SUMMARY OF THE INVENTION

A system for providing video telephony over a cable access network Infrastructure provides simultaneous and converged video, voice, and data bilateral communications (“video telephony”) over an existing cable TV infrastructure. In one aspect, video telephony is implemented via a set-top-box located at cable TV customer premise, a media gateway located at a cable TV distribution hub or headend, and video telephony software switch located at the headend and/or a location within the Internet or a managed data network.

In another aspect, a content delivery network, an application network, and a communication network are integrated into a coherent structure for data, voice, and video conferencing. In one particular embodiment, video, voice, and data bilateral communications are converged without modifying an existing cable TV infrastructure.

The foregoing, and other features and advantages of the invention, will be apparent from the following, more particular description of the preferred embodiments of the invention, the accompanying drawings, and the claims.

### BRIEF DESCRIPTION OF THE DRAWINGS

For a more complete understanding of the inventions described herein, reference is now made to the following descriptions taken in connection with the accompanying drawings in which:

FIG. 1 illustrates a video telephony system according to an embodiment of the invention;

FIG. 2 illustrates spectrum separation at a cable modem termination system according to an embodiment of the invention;

FIG. 3 illustrates a media gateway according to an embodiment of the invention;

FIG. 4 illustrates a media and call signaling system according to an embodiment of the invention;

FIG. 5 illustrates a TCP splicing proxy system according to an embodiment of the invention;

FIG. 6 illustrates an L4-7 switching system according to an embodiment of the invention;

FIG. 7 illustrates a network architecture and videophone call flow according to an embodiment of the invention;

FIG. 8 illustrates injection of a media streams during a call at a media gateway according to an embodiment of the invention;

FIG. 9 illustrates a mixing of media streams for multiparty videoconferencing at a media gateway according to an embodiment of the invention;

FIG. 10 illustrates a software switch logic module according to an embodiment of the invention;

FIG. 11 illustrates application signaling and TCP splicing among two parties and a third party web server during a 3-party videoconference according to an embodiment of the invention; and

FIG. 12 illustrates web caching according to an embodiment of the invention.

### DETAILED DESCRIPTION OF THE PREFERRED EMBODIMENTS

The example embodiments described below are described in the context of systems and methods for enabling converged and integrated telecommunications services over an existing cable TV infrastructure. More specifically, the example embodiments are described in the context of providing end-to-end video telephony and related applications for multimedia content delivery and distribution over a hybrid fiber coax network. It will be understood, however, that the systems and methods described herein can be adapted to any type of bilateral communications comprising video, voice, and/or data.

It should be noted that for purpose of this specification and the claims that follow, the term “Video telephony” is intended to comprise full-duplex, real-time audio-visual communication among two or more end users. Further, for purpose of this specification and the claims that follow, the term “voice” is intended to comprise real-time audio.

A primary challenge of video telephony arises from the fact that full-motion, high-resolution video data requires far more bandwidth than audio data. Moreover, because the existing cable TV infrastructure is expansive and nearly exhaustive within large metropolitan areas, it is preferable to offer video telephony without substantial infrastructure upgrade and/or reconfiguration. Accordingly, video telephony can, for example, be implemented via a set-top box located at each participating party's site, a number of media gateways located at one or more cable TV distribution hubs or headends, and a number of software switches located at one or more headends and/or within the Internet or a managed data network.

The set-top box can, for example, be configured to provide an interface for a participating party to send and receive voice, video, and data converged transmissions, all of which will collectively be referred to in this specification and the claims that follow as “media”. The media gateway can, for example, be configured to handle both in-band, i.e., media, and out-of-band, i.e., call signaling, transmissions. As will be described in detail below, a media gateway can comprise a switching core that directs the out-of-band transmissions to the software switch. The software switch can, for example, be configured to manage all out-of-band signaling and to control the operation of the media gateway.

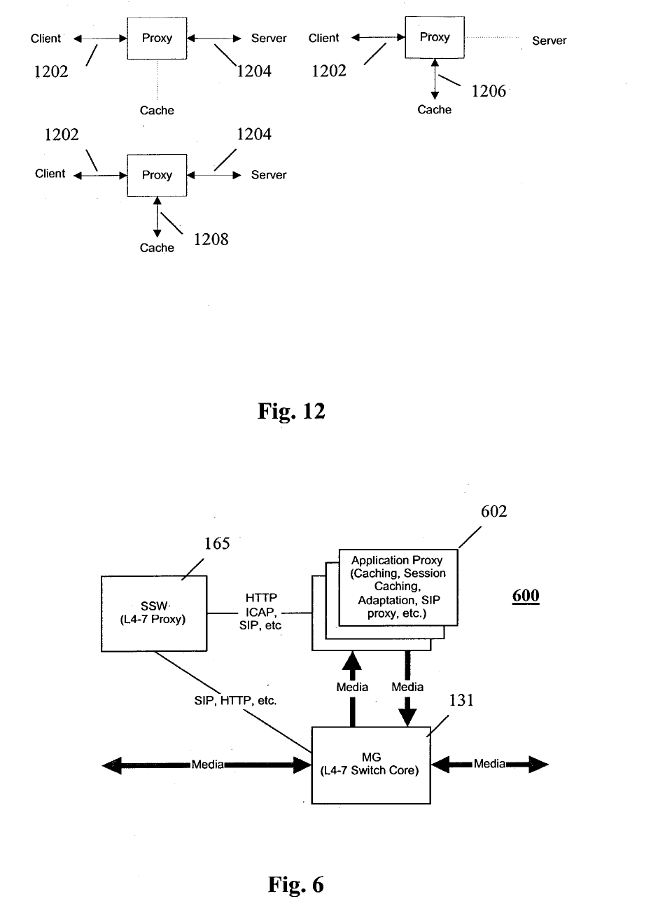

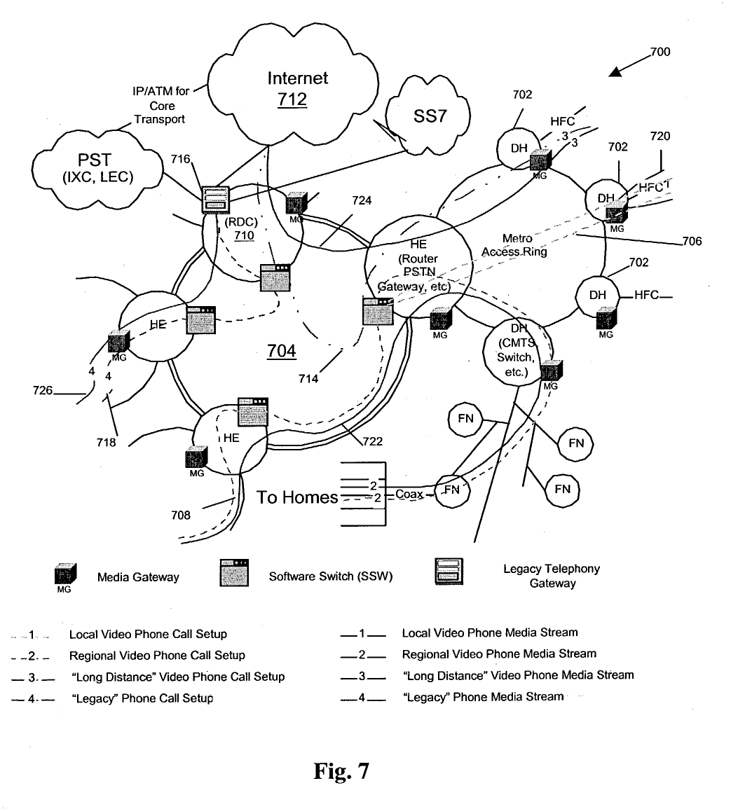

FIG. 7 illustrates a communications network 700 configured to implement videophone call flow in accordance with the systems and methods described herein over an existing Cable TV HFC access network. Each headend (HE) comprises a software switch (SSW) and each distribution hub 702 comprises a media gateway (MG). In one embodiment, a distribution hub 702 can comprise two media gateways for redundancy. In a typical HFC infrastructure, one headend is linked to five distribution hubs 702. Therefore, one software switch can be interfaced with 10 media gateways.

Media and call signaling is illustrated in FIG. 7 for four different types of calls. In FIG. 7, the call signaling is related to call setup, while the media is related to actual media sent back and forth between parties. The call signaling for local calls, where both parties are interfaced with the same headend, is illustrated by path 706. Thus, call signaling received from a calling party is routed by a media gateway and forwarded via a software switch to the called party. Once the call is setup, the media path, or media stream, then follows path 720.

The call signaling for regional calls, where both parties are within the same metro core ring 704 but interfaced with different headends, is illustrated by path 708. Here, signaling received from a calling party is routed through a media gateway and forwarded to the called party via two software switches, one located at each party's headend. Once this type of call is setup, the media stream follows path 722.

The call signaling for long distance calls, where both parties are not in the same regional data center (RDC) (710) but is in the same video telephony network, is illustrated by path 714. Here, signaling received from a calling party is routed by a media gateway and forwarded via a software switch interfaced with the calling party's headend and a software switch interfaced with RDC 710 prior to transmission over the Internet 712 to the called party. After such a long distance call is setup, the media stream follows path 724.

The call signaling for legacy calls, where at least one party is outside the video telephony network as a PSTN end user, is illustrated by path 718. Thus, signaling received from a calling party is routed by a media gateway and forwarded via a software switch at the calling party's headend and a software switch at RDC 710 prior to transmission by a legacy telephone gateway 716 over the PSTN. The media stream can then follow path 726, as illustrated in FIG. 7.

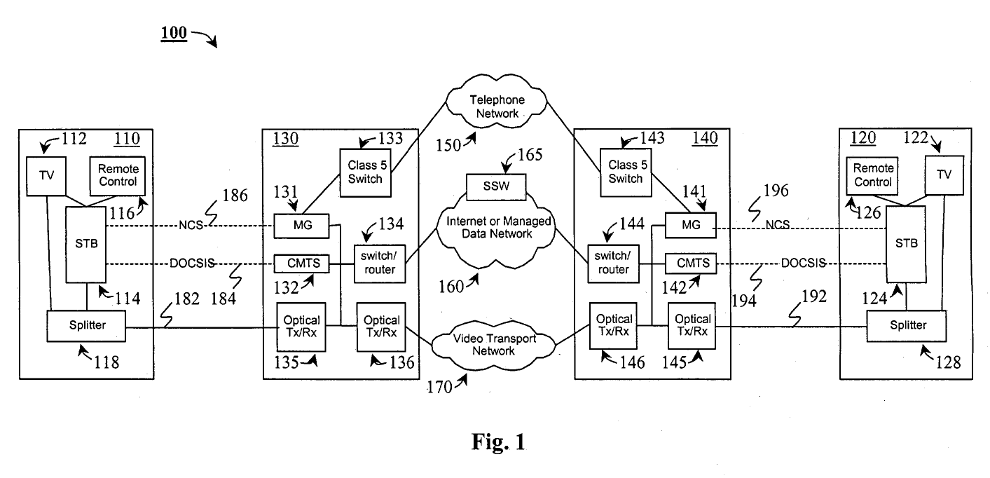

For all four types of calls described above, the media stream arrives at the destination via at least one media gateway under the control of a software switch. The operation of exemplary media gateways and exemplary software switches is described in detail below beginning with FIG. 1, which illustrates an exemplary video telephony system 100 configured in accordance with one embodiment of the systems and methods described herein. Thus, video telephony system 100 can be configured to enable video telephony communications between a plurality of telecommunication customers, or parties. In order to simplify the present discussion, however, the features and functionality of video telephony system 100 are described in relation to communication between two parties. From this description it will be apparent, however, that system 100 can facilitate video telephony communications between three or more participants as well.

As illustrated in FIG. 1, one participant employs customer premise equipment (CPE) 110 comprising an audio-visual display device 112, such as a television, video monitor with audio speaker, or the like; a set-top box 114, an optional remote control 116 for controlling display device 112 and/or set-top box 114; and an optional splitter 118 for splitting an incoming signal to one or more locations within the premise, for example, to a stand-alone television set. Similarly, another participant employs CPE 120 comprising an audio-visual display device 122; a set-top box 124, an optional remote control 126 for controlling display device 122 and/or set-top box 124; and an optional splitter 128. To provide bilateral video and audio communications, CPEs 110 and 120 each comprise video and audio capture devices (not shown), such as a video camera, microphone or like devices, the implementation of which is well known and will not be described in detail here. The video and audio capture devices can, depending on the embodiment, be linked to, or included in, an audio-visual display device 122 or set-top box 124.

Each customer premises is linked to a distribution hub or a headend employed by a cable television service provider. For example, CPE 110 is linked to headend 130 and CPE 120 is linked to headend 140. Headend 130 comprises a media gateway 131, cable modem termination system (CMTS) 132, a telephone switch 133, network switch 134, and optical transceivers 135 and 136. Headend 140 comprises a media gateway 141, CMTS 142, a telephone switch 143, network switch 144, and optical transceivers 145 and 146. Transceivers 135 and 145 respectively communicate with CPEs 110 and 120, while transceivers 136 and 146 communicate with a video transport network 170 generally within a wider spectrum range than transceivers 135 and 145. Transceivers 135 and 145 provide spectrum separation to and from CMTS 132 and 142, respectively, for Internet access. Transceivers 136 and 146 perform relaying of unidirectional broadcasting content.

Telephone switches 133 and 143 link respective headend units 130 and 140 to a telephone network 150. Telephone network 150 can be any type of telephone network, such as a public switched telephone network (PSTN), integrated services digital network (ISDN), fiber distributed data interface (FDDI) network, cellular network, or a combination thereof. Telephone switches 133 and 143 can be legacy PSTN circuit switches, such as a class 5 switch, which provides legacy telephone communications and signaling. In an alternative embodiment, telephone switches 133 and 143 are not present at headend units 130 and 140. For example, a telephone switch or any other equipment for connecting to telephone network 150 can be located at a regional data center (RDC), which connects the headend to telephone network 150 as well as other headend units on a metro ring. In either case, telephone switches 133 and 143 should be included if legacy telephony is to be supported.

Network switches 134 and 144 link respective headend units 130 and 140 to a communications network 160. Communications network 160 is preferably the Internet or a managed data network, but alternatively can be, or additionally include, any type of communications network, such as, but not limited to a wide area network (WAN), a local area network (LAN), an intranet, a satellite network, a wireless LAN network, e.g., Wi-Fi IEEE 802.11, a DSL broadband access network, or any combination thereof. A managed data network refers to a network that provides control over application services. In one embodiment, for example, communications network 160 is and Internet protocol (IP) network.

Video transport network 170 is a conventional video transport network comprising a number of satellite communication systems and/or antenna systems for reception and delivery of any type of information, such as television broadcast content, or the like, to customers. In certain embodiments, headend units 130 and 140 can comprise satellites and antennas to receive broadcast channels. Generally, a conventional video transport network 170 comprises optical fiber rings, which are also used for data transport. As such, Internet access service is typically referred to as being overlaid on a video transport network 170.

Headend units 130 and 140 are not necessarily linked together unless both of them happen to be located on the same metro core ring. If they are not directly linked together, they communicate with each other via: (1) network 160 for data or any data-related content, and (2) network 170 for regular video signal, such as cable TV, pay-per-view, video-on-demand, etc. It should be noted that network 170 is the real “physical” network, i.e., the current HFC infrastructure implemented by an MSO. Although network 160 could have a real “physical” network outside of the HFC infrastructure, the portion of network 160 within MSO's infrastructure is really an overlay on top of network 170. The current available cable modem Internet access service is, for example, established as such an overlay.

Each headend 130 and 140 distributes media content, such as, cable television channels, pay-per-view, video-on-demand, and facilitates bilateral communications with respective CPEs 110 and 120 on a communications medium such as a HFC distribution network 170. In a typical HFC configuration, the communications medium comprises a node (not shown) for converting communication signals between optical formats implement at headends 130 and 140 and electrical formats implemented at CPEs 110 and 120. For example, in a downstream direction, a node receives an optical signal from a headend, converts the optical signal to an electrical signal and then distributes the electrical signal over a coaxial cable to one or more CPEs. In the opposite direction, information is received from a CPE in electrical format at the node, which converts the electrical signal into an optical format for forwarding upstream to the headend.

Set-top boxes 114 and 124 tune, decode, and de-modulate source information in downstream communications received from headends 130 and 140 via communications links 182 and 192 respectively. In one embodiment, set-top box 114 comprises a cable modem (not shown) and a telephony interface (not shown). The cable modem can be configured to enable Internet protocol (IP) transport over communications link 184 to provide data connectivity between respective CPE 110 and CMTS 132 of headend 130. In one implementation, for example, the cable modem of set-top box 114 communicates with CMTS 132 according to a cable modem communication standard, such as DOCSIS. The telephony interface can comprise a multimedia terminal adapter (MTA), which enables a type of network based call signaling (NCS), such as PacketCable™ via link 186 for facilitating video telephony. NCS signaling can be based on either TCP or UDP. In one implementation, extensions to PacketCable™ specification are made for video calls. For example, set-top box 114 can include an embedded MTA for audio and video telephony service. The embedded MTA can comprise a cable modem implementing DOCSIS as above. However, set-top box 114 can further comprise software modules for call management and hardware chips for digital tone generation, silence suppression, etc. The embedded MTA can be configured to provide hooks for a legacy telephony handset and to allow applications to talk to underlying network equipment. Although only the communications between CPE 110 and headend 130 are described herein with particularity, the description is applicable to the communications between CPE 120 and headend 140 enabled via communication links 192, 194, and 196.

It should be noted that in an embodiment where the participants' CPEs are connected to the same headend, there is no need for the complexity of managing the IP network between headends for calls or sessions, because the participants share the same media gateway and soft-switches.

Communication links 182, 184, and 186 are not necessarily links in the sense of separate physical mediums. Rather, communication links 182, 184, and 186 can designate a discrete frequency band(s) or communication channels, which carry a type of information. For example, link 182 can comprise cable television channels broadcast in the range of 54 MHz to 550 MHz. Link 184 can comprise a 6 MHz downstream channel located in the range of 550 to 860 MHz and an upstream channel of 3.2 MHz located in the range of 5 to 42 MHz. These channels and frequency ranges are exemplary, and if necessary, can be modified depending on the desired bandwidth allotment to each participant.

Video telephony can, for example, be facilitated over communication links 184 and 186. In such an implementation, communications link 184 can be configured to carry the in-band video telephony information comprising actual video, voice, and/or data communications, the convergence of which is herein referred to as “media”, between participants. In one embodiment, in-band communications are transmitted according to a real-time transport protocol (RTP), which is an Internet protocol for streaming real-time data including audio and video and runs on top of a user datagram protocol (UDP) protocol, although the specification is general enough to support other transport protocols. In another embodiment, media is communicated using UDP or a combination of UDP and RTP on UDP.

Communications link 186 can be configured to facilitate out-of-band signaling for call set-up, call break-down, and other call administrative tasks. As will be made clearer from the following description, media gateway 131 can be configured to handle all in-band and out-of-band video telephony signals in conjunction with CMTS 132 and software switch 165 located anywhere in network 160. Although software switch 165 is shown located on the network, it can also be located at a headend, such as headend 130. Moreover, software switch 165 can represent many software switches, which are often implemented to handle high availability, i.e., high redundancy, in a way to distribute call signaling processing among multiple software switches. Software switch 165 handles out-of-band telephony signals for call management between two participants and as will be explained further, controls one or more appropriate media gateways 131. In one embodiment, each media gateway 131 can be configured to use several software switches 165 for high availability and load balancing. To achieve high availability, 99.999% for example, a media gateway 131 can, for example, configure software switches 165 at other headends as backup software switches. Therefore, even if a software switch 165 at one headend failed, there are four more software switches 165 that could be used to distribute the signaling and application processing load from the headend.

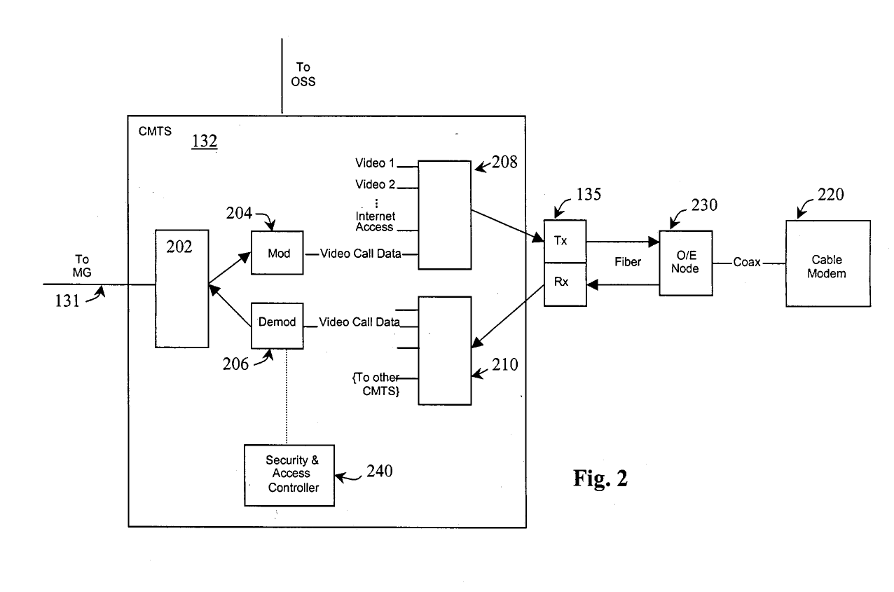

According to one embodiment, CMTS 132 serves, among other things, as a video call data bridge between a cable modem at set-top box 114 and media gateway 131. Particularly, CMTS 132 can be configured to redirect all RTP traffic to media gateway 131. FIG. 2 is a diagram illustrating an example embodiment of a CMTS 132 configured in accordance with the systems and methods described herein. As can be seen, CMTS 132 comprises a network termination 202, which terminates a connection from CMTS 132 to media gateway 131; a modulator 204; demodulator 206; downstream combiner 208; and upstream splitter and filter bank 210. In operation during a video call, in-band video telephony communications can be received, possibly in compressed format, from media gateway 131 at network termination 202, which forwards the video call data to modulator 204. Modulator 204 modulates the video call data for downstream transmission according to, for example, a quadrature amplitude modulation (QAM) scheme. Prior to transmission, downstream combiner 208 merges the modulated video call data with a number of other data streams, such as internet traffic and regular video broadcasting signals, such as channel 1 (video 1) and channel 2 (video 2), into a combined signal, which is then transmitted downstream by optical transceiver 135 to a cable modem 220.

As illustrated, optical/electrical (O/E) node 230 is provided to convert between optical and electrical formats along the downstream and upstream communication paths. Upstream splitter and filter bank 210 receives video call data from cable modem 220 via an upstream channel. Upstream splitter and filter bank 210 separates the spectrum for video telephony from the spectrum used for other data, such as Internet data. For example, upstream splitter and filter bank 210 can be configured to split the radio frequency spectrum carrying video call data contained within the upstream channel and forwards it to demodulator 206. A portion of the spectrum that is allocated for data other than video call data is forwarded to another CMTS. Demodulator 206 demodulates according to, for example, a quadrature amplitude modulation (QAM) or quadrature phase shift keying (QPSK) scheme the video call data into a format suitable for forwarding to media gateway 131 via termination 202.

In certain embodiments, CMTS 132 can further comprise a security and access controller 240, which can be configured to handle encryption and decryption of data if necessary. Any cryptographic technique can be employed. The type of cryptographic technique employed can, therefore, depend on the requirements of a specific implementation. As can be seen, CMTS 132 can also be connected to an operational support system in certain embodiments.

In one particular embodiment, media gateway 131 or 141 can comprise a Layer 4 (L4) switching core. Layer 4 refers to the fourth layer of a seven-layer set of hardware and software guidelines known as the open systems interconnection (“OSI”) model developed by the International Organization for Standardization (“ISO”). The OSI model is a set of protocol standards designed to enable computers to connect with one another and to exchange information with as little error as possible. This protocol model standardizes overall computer communications and forms a valuable reference defining much of the language used in data communications. Layer 4 of the OSI model is the transport layer, which coordinates communications between a network source and one or more destination systems. At Layer 4, the transmission control protocol (TCP) and user datagram protocol (UDP) headers include port numbers that uniquely identify which application protocols, e.g., HTTP, SMTP, FTP, etc., are included with each packet. A destination system uses the port numbers to enable a receiving end computer system to determine the type of Internet protocol IP packet it has received and to hand it off to the appropriate higher-layer software. This additional information provided by the TCP/UDP port number is the basis for Layer 4 switching. Layer 4 switches make forwarding decisions based not only on the media access control (MAC) address, which is the basis for layer 2 switches operating at the data-link layer; and IP address, which is the basis for layer 3 switches operating at the network layer; but also on the application to which a packet belongs.

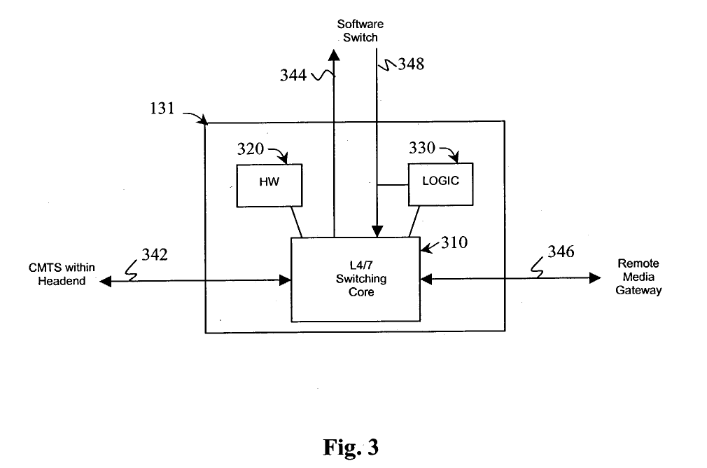

FIG. 3 is a diagram illustrating a media gateway 131 configured in accordance with one embodiment of the systems and methods described herein. Media gateway 131 comprises a switching core 310, such as a L4/7 switching core, a number of hardware components 320, and logic 330 for implementing one or more application program interfaces. Switching core 310 can be a programmable switching core that is highly scalable and based on a common switch interface (CSIX) specification, such as CSIX-L0, CSIX-L1, CSIX-L2, etc. Switching core 310 can also include an off-the-shelf network processor, application specific integrated circuit (ASIC), field-programmable gate array (FPGA), or a combination thereof. Switching can be performed with complete fabric redundancy, i.e., switching core 310 can comprise two identical halves, so that if one half fails the other half can take over. Media gateway 131 can comprise an “open” capability and flexibility for customizing its design. For example, new switching functionality can be downloaded to the network processor and FPGA in switching core 310.

Hardware 320 can comprise off-the-shelf standards-based media-resource and/or application-specific cards or the like for implementing enhanced services such as, but not limited to, advanced speech recognition (ASR), interactive voice response (IVR), text-to-speech (TTS), voice over IP, security protocol acceleration, encryption, compression/decompression (CODEC), and/or asynchronous transfer mode (ATM) systems for integrated switch/gateway system solutions.

Logic 330 can be configured to execute an open application program interface (API) middleware and to provide easy control and programming, rapid development of new applications, and porting of existing applications of media gateway 131. For example, flash resident software modules may be downloaded to storage (not shown) within media gateway 131 for execution on logic 330. For purposes of this specification and the claims that follow, the term “logic” is intended to denote any type of processor, circuitry, code, software, and the like, that is configured to perform the functions described herein.

It should be noted that extensive use of open hardware and software standards enables telecom solutions normally implemented on separate platforms to be integrated on a single platform for cost savings and improved efficiency. Thus, media gateway 131 can be configured such that service application programs co-reside on the same platform as the switching, media resource, and application-specific modules in order to enable compact cost-effective solutions.

In operation, switching core 310 can be configured to receive in-band and out-of-band traffic, i.e., media and call signaling, from a CMTS via link 342 and to separate the call signaling data from the media data stream. For example, NCS signaling data can be identified via UDP port number by switching core 310 and routed via TCP/UDP splicing to a software switch via link 344. Signaling based on SIP or NCS is a L7 protocol. The media data is forwarded via link 346 to a remote media gateway associated with another participant. As will be described, media gateway 131 is controlled by a software switch via link 348 implementing media gateway control protocol (MGCP) or MEGACO/H.248. Further, logic 330 will include functions that provides switch management via SNMP, detailed call record (DCR) for billing information, etc.

During call signaling, software switch 165 identifies the call destination address either directly or via address translation. If the destination address is identified, software switch 165 requests QoS signaling between the two involved media gateways, e.g., media gateway 131 and the remote media gateway and the QoS signaling for each HFC part, i.e., the so-called segmented QoS. If the destination address is not found, software switch 165 looks at a routing table to forward the call signaling message to another software switch 165 were the destination address can be determined. In the latter case, it is the responsibility of each software switch 165 to request the QoS signaling and possibly querying the QoS policy servers via common open policy service (COPS) protocol. Once signaling is done, software switches 165 control the appropriate media gateways 131 along the media stream path to open the gate for the rest of call conversation and trigger accounting for the session.

Media gateway 131 operates regardless of whether CMTS 132 assigns bandwidth through dedicated or dynamic spectrum allocation. A dedicated spectrum can be used for video telephony so that other services will not be interrupted by video calls. However, bandwidth may be wasted if only a few calls are present in the dedicated spectrum. Dynamic allocation employs a policy to vary the bandwidth allocated for video telephony service. For example, a policy can be established to limit the bandwidth for all upstream calls managed by a particular CMTS 132 to not more than 45 Mbps. When only a few calls are being made, more bandwidth can be allotted for Internet access. However, when more calls are being executed, bandwidth that was used for Internet access can be allotted for call sessions. The choice of a spectrum allocation method depends on the specific implementation, e.g., on the service level agreement between an end user and an MSO.

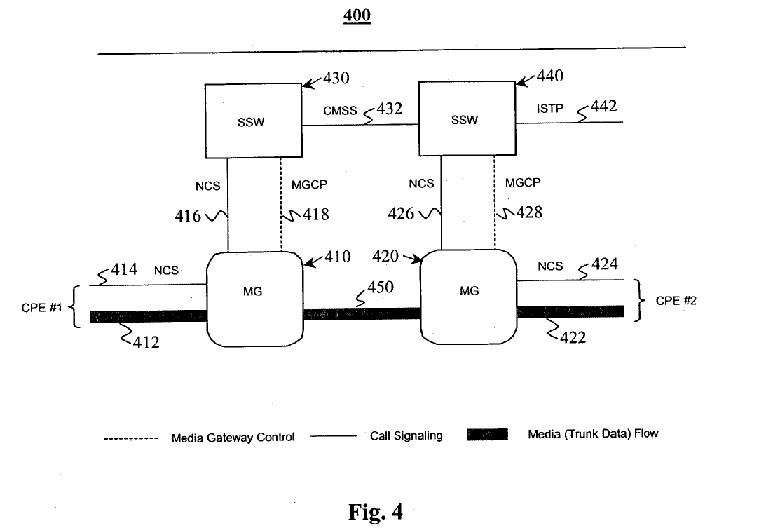

FIG. 4 is a diagram illustrating an example media and call signaling system 400 for a two-party video telephony communication configured in accordance with the systems and methods described herein. Particularly, signaling system 400 segments the PacketCable™ or NCS based call signaling between software switches 430 and 440, while media is handled between media gateways 410 and 420 during a video telephony communication. Thus, for a two-party video telephony communication, call signaling system 400 comprises media gateways 410 and 420, which may or may not be identical to the media gateways in earlier figures, and software switches 430 and 440. As shown, media gateways 410 and 420 receive media via links 412 or 422 and call signaling via links 414 or 424 from respective CPEs. Media gateways 410 and 420 can be configured to then redirect NCS traffic to associated software switches 430 or 440 via links 416 or 426.

For example, media gateways 410 and 420 can be configured to detect the NCS packets that belong to NCS call signaling based on port number of L4/7 switching and establish, using a MAC address, IP address, port number, physical port, or combination thereof, a switching table, e.g., network address translation (NAT) table, to mark the path being used between a client and the associated software switch 430 or 440. In one embodiment, the switching table can comprise information relating to the protocol used and type of service implemented, and can also be chained to additional tables to provide efficient switching. For example, the latter may implement a cookie based persistency to allow connections pertinent during a session.

The NCS traffic can be based on session initiation protocol (SIP) with some extension layered on top of RTP (via UDP/TCP). Session initiation protocol is a signaling protocol for Internet conferencing, telephony, presence, events notification and instant messaging. The protocol initiates call setup, routing, authentication and other feature messages to endpoints within an IP domain.

Media can be transferred between media gateways 410 and 420 along media trunk 450. Software switches 430 and 440 can control media gateways 410 and 420 via respective links 418 and 428. Software switches 430 and 440 can, for example, control respective media gateways 410 and 420 using a media gateway control protocol (MGCP) or in accordance with the ITU H.248 specification.

Software switches 430 and 440 communicate with each other using a call management software system (CMSS) via link 432. CMSS is a PacketCable™ 1.2 specification. It is required for across zone call signaling and QoS management. In this case, software switch 430 or 440 can act as a SIP proxy. Third party SIP servers that are linked to software switch 430 or 440 can also be involved. Each software switch 430 and 440 along the signaling path, builds up its namespace for the session. CMSS coordinates software switches to obtain the acceptable namespace that includes the subscriber namespace of all parties, the call parameters, the end terminal device capabilities, application parameters and network and switching parameters via switching platform application portal (SPAP), etc.

Layer 4 switches make forwarding decisions based on an application layer information and forward data in the application layer. After making forwarding decisions, some existing proxies and most content-based switches increase their forwarding performance by TCP splicing, which releases them from maintaining TCP endpoints and allows them to forward data by packet forwarding. Two separate TCP connections can, for example, be terminated at a common host and “glued” together into a single connection between two end systems, where the single connection preserves TCP end-to-end semantics. This process, however, often is only useful for two party applications and is not used for multi-party applications, such as videoconferencing, at present. TCP splicing prevents proxies and content-switches from using the application layer information for forwarding decisions. Thus, the existing content-based switches cannot hand off pipelined HTTP transactions, which can greatly reduce client perceived latencies.

Unlike a traditional switching core, where the switch applications are located inside the switch core, the switch applications are moved outside the switching core to a software switch, e.g., software switch 430 or 440, in the embodiments described herein. Thus, only the switching core applications are maintained in a media gateway 410 or 420.

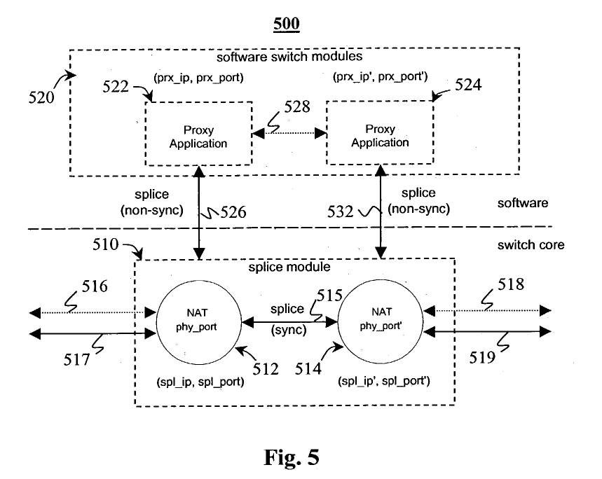

FIG. 5 is a diagram illustrating an exemplary TCP splicing proxy system 500 configured in accordance with one embodiment of the systems and methods described herein. As explained above, splicing can be used to combine and forward multiple information signals. The top half of FIG. 5 illustrates the switch applications, which as explained can be located in software switch 165, and the bottom half illustrates the switching core, e.g., switching core 310 in media gateway 131. As can be seen, TCP splicing proxy system 500 comprises a splice module 510 and a proxy module 520 comprising proxy applications 522 and 524. Although only proxy applications 522 and 524 are illustrated in the figure, any number of proxy applications of one software switch 165 or multiple software switches 165 can be involved when making a switching decision in a live call session. Particularly, each proxy application 522 and 524 can be a module within a software switch 165 and can be configured to handle a particular kind of application header processing, such as signaling proxy (SIP proxy) for call signaling and session management, HTTP proxy for web browsing, caching proxy for storage and forward, etc. Splice module 510 can comprise network address translation (NAT) tables 512 and 514. NAT is an Internet standard that enables a local-area network (LAN) to use one set of IP addresses for client traffic and a second set of addresses for server traffic. A NAT table makes all necessary IP address translations.

A more flexible design is used in splicing module 510 such that proxy applications 522 and/or 524 can be physically located either inside or separated from splicing module 510. The former approach, for example, is used in existing L4/7 products where the proxy connection “prx” is “local” to splicing module 510. The systems and methods described herein are capable, however, of implementing the latter by building programmable proxies either in forward or transparent mode. In this case, the “prx” is actually the connection of splicing module 510 to/from proxy applications 522 and 524. For example, the proxy applications in two PC based appliances can be physically in separate devices if, for example, a web proxy application and a streaming proxy application were split, such that one was in one device and the other in another device.

A programmable proxy allows value to be added to proxy applications, such as constructing switching or routing table out of band, establishing per-connection-based accounting and providing subtle control of QoS policy. This can make more sense in a content delivery network where the data comprises applications. By programming the proxy applications, e.g., web switching, streaming switch, etc., system 500 can be adapted to other network infrastructure and to different types of content.

The translation structure also contains the addresses and port numbers that assists the packet splicing at either client or server port. In general, the translation can happen at both connection establishing (non-synchronized) and splicing phases. It noted that since the packet processing is above the Ethernet link layer and the IP layer, the splicing module can be set up in either routing or bridge mode. This allows different IP addresses to be assigned for the splicing module and the proxy applications 522 and 524. It also allows the use of a combination of both the IP address and port number as well as the Ethernet address to segment the network. The proxy IP and port number can be statically setup in the routing table of splicing module or dynamically propagated to the module. In an alternative embodiment, the lower layer can be set up for masquerading IP address and port number. Typically, however, this is not preferred because it is either too processing intensive or lacks L7 information required when making a load balancing decision.

In one embodiment, out-of-band signaling from the client is transmitted via connection 516 and is forwarded via connection 526 to software switch 520 via address translation by NAT, or by splicing module 512 when the L7 protocol header is modified. A connection can be made between a client and proxy application 522. In call signaling, proxy application 522 can be the CMS module. In web connection, proxy application 522 can be the HTTP proxy. Proxy application 522 can be configured to connect with other proxies, such as proxy application 524 via connection 528 for client requests. Proxy application 524 can be configured to employ, for example, NAT 515 via connection 532. The last proxy application, e.g., proxy application 524, which can be the first proxy application in certain implementations, makes the connection to the destination server, or the called party through another address translation table 514 to a media gateway via connection 518. Once a connection is established and there is no need for proxy application attention, the connections to proxy applications 522 and 524 are disconnected. The NAT, or splicing module 510, can be configured to simply close the loop and the trunk data flow through connections 517, 515, and 519 from one media gateway (not shown) to another media gateway (not shown).

Accordingly, a software switch 165 collects, processes, and modifies the packets that contain application protocol headers. For HTTP, usually less than 2% of TCP packets are routed to software switch 165 and the majority traffic is still handled by the media gateway switching core 310 via trunk data splicing. For pure call signaling, all data is passed from switching core 310 to software switch 165.

FIG. 6 is a diagram illustrating an exemplary switching system 600 configured to switch in accordance with one embodiment of the systems and methods described herein. For example, in one embodiment, switching system 600 is a L4-7 switching system. Switching system can be configured to include a media gateway 131 and a software switch 165, which can be configured to implement enhanced service via application proxies or servers 602. In the example of FIG. 6, application signaling can be handled by software switch 165, which can be configured to build the namespace for the session of all parties. In one implementation, SIP is used not only for the calling session signaling, but also for implementation of the applications during the session. If software switch 165 identifies that the calling party needs enhanced service, for example content adaptation, it can be configured to use, e.g., Internet content adaptation protocol (ICAP) to request such service. In this case, the media can be routed to a service server 602 for bit translation before going out of media gateway 131. System 600 can also provide session or application service that can help speed up data retrieval, save bandwidth, and improve user experience.

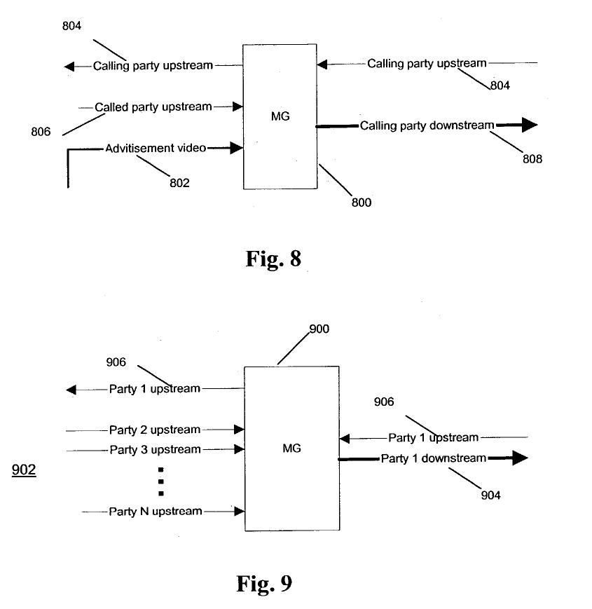

FIG. 8 illustrates an exemplary method for injection of a media streams during a call at a media gateway 800 in accordance with the systems and methods described herein. In the example of FIG. 8, an injected media stream 802, such as a video advertisement at the beginning or end of a call or a notification of an incoming call that occurs during an existing call, can be merged by media gateway 800 with the respective upstream 804 and downstream 806 media streams of the called and calling parties. Thus, for example, after the injected media stream 8024 is merged with the called parties downstream media 806, a merged downstream media stream 808 results. The bandwidth of the merged downstream media stream 808 is increased to handle the merged media stream 808 so that video and audio quality does not degrade due to the injected media stream 802. Generally, the upstream bandwidth is not affected. Video advertisement can be transmitted over link 160 and/or retrieved from service server cache server 620.

FIG. 9 is a diagram illustrating an exemplary method for mixing of media streams for multiparty videoconferencing at a media gateway 900 in accordance with one embodiment of the systems and methods described herein. Thus, media gateway 900 can be configured to support video conferencing between (N) number of parties without degrading the video signals of any of the (N) parties as long as the downstream capacity does not exceed the total allotted bandwidth. It should be noted that the number of parties (N) and their picture quality is not limited by the down stream traffic, but by the size of each party's terminal video set. In one specific implementation, media gateway 900 supports both unicast and multicast IP transport for the videoconference. For example, software switches 165 along the signaling path can be configured to determine the best transport mode, e.g., unicast or multicast. Often, for two-party video calls, there is no need for IP multicasting. However, if more parties join the conversation, IP multicasting can be used for efficient media transport and thus bandwidth saving. In such a situation, software switches 165-involved in the signaling can be configured to control and open gates for media gateways 900 of each party to use IP multicast transport.

Thus, in FIG. 9, media gateway 900 can be configured to handle the (N) party video conference, by combining the upstream video conference signals 902 of parties 2 through N into a single downstream signal 904. The upstream signal 906 remains unaffected. Again, as long as the bandwidth of the combined signal 904 does not exceed the overall allotted downstream bandwidth, then video signal quality will be unaffected.

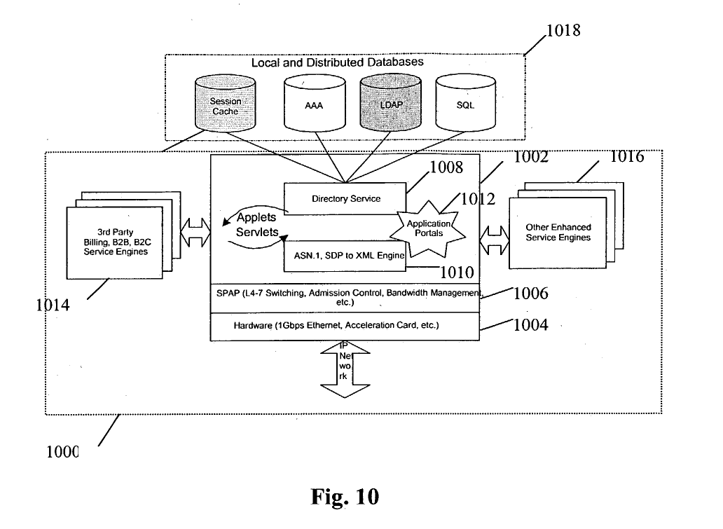

FIG. 10 demonstrates an exemplary software switch logic module 1000 configured in accordance with one embodiment of the systems and methods described herein. Logic module 1000 can be implemented using a web transaction based software switch 1002 for easy integration with a plurality of applications 1014, such as billing applications, B2B applications, B2C applications, and service level agreement portals. Software switch 1000 can also be configured to support applications 1010, such as ASN.1, XML, and session cache, that help to reduce processing overhead and increase portability. Software switch 1000 can also comprise a directory service API 1008, which can allow access to services 1018 including, as illustrated, session cache, AAA (Authentication, Authorization and Accounting), LDAP (Lightweight Directory Application Protocol) and SQL for widely relational database portal, such as Oracle, DB2, etc.

As illustrated, core software component 1002 can comprise a switching platform application portal (SPAP) middleware 1006 that can be configured to operate in redundancy and/or load-balance modes for reliable access and control of software switch 1000 through a standards-based or open API. This can enable service providers, or any third-party vendor, to write new applications 1016 for, or port existing applications to, software switch 1000. Further, SPAP middleware 1006 can also enable the use of a wide variety of development tools and off-the-shelf software for rapid programming. Accordingly, new services can be developed, configured, and deployed just as soon as opportunities appear. In one particular implementation, SPAP middleware 1006 can comprise, or enable functions including CMS, MGC, QoS policy and signaling, Proxy CGI, ANS, COPS, AAA, and enhanced L4-7 switching. MGC can consist, for example, of basic switching and routing, data transport via L7 IP multicast, and IP unicast via multiple connection TCP splicing.

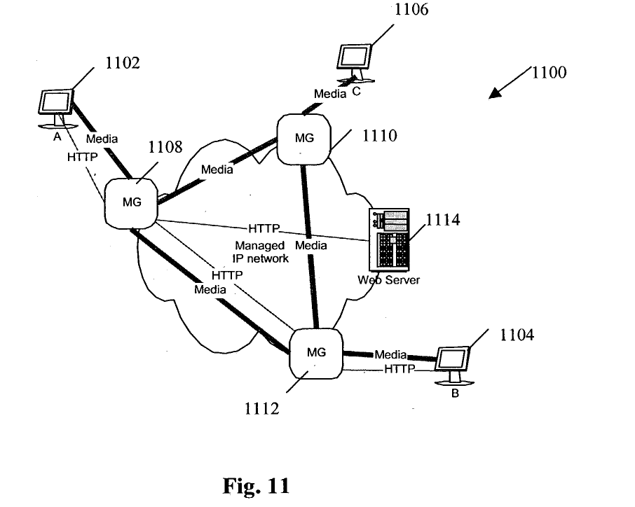

Accordingly, a video telephony system configured in accordance with the systems and methods described herein can provide basic signaling and transport layer support for enhanced services. As an example, FIG. 11 illustrates an exemplary video telephony system configured in accordance with the systems and methods described herein and in which two users browse the same web page simultaneously. Thus, one user can use terminal 1102 to browse the web page, while the other uses terminal 1104. The term “terminal” is intended to mean any type of terminal system 110, or other computing device that is capable of performing the functions described herein. Viewing the web page simultaneously requires a signaling context initiated by one involving both users and a web server 1114 as the terminations. The signaling involved can use a media gateway 1108 as the TCP proxy to stream data from web server 1114 to both terminals 1102 and 1104. In order to synchronize the displaying, the data arriving at both terminals 11102 and 1104 should arrive nearly at the same time. The TCP splicing for multiple connections offers a way to ensure that such synchronicity is achieved, e.g., via unicasting. In an alternative implementation, a reliable multicast transport protocol (RMTP) can be used. But, such an implementation requires either web server 1114 to support RMTP or a proxy that retrieves the web page from web server 1114 and opens a RMTP session among terminals 1102 and 1104 and itself to deliver the retrieved page.

FIG. 12 illustrates example connections that can be created during web caching in a system configured in accordance with the systems and methods described herein and where packets are directed among three TCP connections. Thus, a client can initiate a TCP connection 1202 to a server, which ends up with a connection to a proxy (transparent mode). The proxy can parse HTTP requests from the client and decide if the request data is already in the cache server 602 by looking at a caching table in memory or secondary storage. If the request data is not cacheable, the proxy makes a connection 1204 to the server. Then the proxy can, for example, simply splice the two connections 1202 and 1204. If, however, the request data is already cached, the proxy can simply retrieve the page from the cache server via connection 1206. In this case, the cache server is just like the original server. The proxy can then splice the two connections 1202 and 1206. Further, data retrieved via connection 1204 from the server can be cacheable. In which case, the proxy can forward the retrieved web page to the client and make a connection 1208 with the cache in order to cache the retrieved web page. The proxy can be configured to splice data from the server to both the client and the cache server.

Other embodiments and uses of the invention will be apparent to those skilled in the art from consideration of the specification and practice of the invention disclosed herein. All references cited herein including all U.S. patents are hereby incorporated herein by reference in their entirety. Although the invention has been particularly shown and described with reference to several preferred embodiments thereof, it will be understood by those skilled in the art that various changes in form and details may be made therein without departing from the spirit and scope of the invention as defined in the appended claims.

What is claimed is;

1. A video telephony system, comprising:
a media gateway configured to receive both in-band and out-of-band signals from a customer premise equipment and to handle the in-band; and
a software switch coupled with the media gateway, the software switch configured to receive the out-of-band signals from the media gateway handle the out-of-band signals.

2. The video telephony system of claim 1, wherein the media gateway is further configured to forward the in-band signals to another media gateway associated with a customer premise equipment for which the in-band signals are intended.

3. The video telephony system of claim 2, wherein the software switch is further configured to identify the intended customer premise equipment based on the out-of-band signals, and establishes a connection with the intended customer premise equipment.

4. The video telephony system of claim 3, wherein the software switch is further configured to identify an address associated with the intended customer premise based on the out-of-band signals and request QoS signaling between the media gateway and the other media gateway associated with the intended customer premise equipment.

5. The video telephony system of claim 4, wherein the software switch is further configured to forward the out-of-band signals to another software switch using a routing table, when the address cannot be identified so that the other software switch can identify the address.

6. The video telephony system of claim 5, wherein the software switch is further configured to request QoS signaling between the media gateway and the other media gateway associated with the intended customer premise once the address is identified.

7. The video telephony system of claim 1, wherein the media gateway is further configured to receive the in-band and out-of-band signals, separate the in-band signals form the out-of-band signals, and route the out-of-band signals to the software switch.

8. The video telephony system of claim 7, wherein the media gateway is further configured to route the out-of-band signals to the software switch using splicing.

9. The video telephony system of claim 1, wherein the media gateway is configured to receive in-band signals from a plurality of customer premise equipment, and wherein the video telephony system is configured to implement a dedicated spectrum allocation for the in-band signals associated with each of the plurality of customer premise equipment.

10. The video telephony system of claim 1, wherein the media gateway is configured to receive in-band signals from a plurality of customer premise equipment, and wherein the video telephony system is configured to implement a dynamic spectrum allocation for the in-band signals associated with each of the plurality of customer premise equipment.

11. The video telephony system of claim 1, wherein the media gateway comprises logic configured to execute an open API middleware.

12. The video telephony system of claim 1, wherein the media gateway is configured to implement at least one enhanced service.

13. The video telephony system of claim 1, wherein the in-band signals comprise a plurality of media signals intended for a plurality of other customer premise equipment associated with another media gateway, and wherein the media gateway is configured to splice the media signals together into one data stream and forward the data stream to the other media gateway.

14. The video telephony system of claim 1, wherein the out-of-band signals comprise a plurality of call setup signals and wherein the media gateway is configured to splice the plurality of call setup signals together and forward the spliced call setup signals to the software switch.

15. The video telephony system of claim 1, wherein the software switch is configured to control the media gateway, and wherein the media gateway is configured to handle the in-band signals under the control of the software switch.

16. The video telephony system of claim 1, wherein the media gateway is further configured to receive in-band signals form another media gateway and to forward the received in-band signals to the customer premise equipment.

17. A video telephony system, comprising:
a set-top box configured to send and receive in-band and out-of-band signals;
a media gateway configured to receive in-band and out-of-band signals from the set-top box and to handle the in-band signals; and
a software switch coupled with the media gateway, the software switch configured to receive and handle the out-of-band signals from the media gateway.

18. The video telephony system of claim 1, wherein the media gateway is further configured to forward the in-band signals to another media gateway associated with a set-top box for which the in-band signals are intended.

19. The video telephony system of claim 18, wherein the software switch is further configured to identify the intended set-top box based on the out-of-band signals, and establishes a connection with the intended set-top box.

20. The video telephony system of claim 19, wherein the software switch is further configured to identify an address associated with the intended set-top box based on the out-of-band signals and request QoS signaling between the media gateway and the other media gateway associated with the intended set-top box.

21. The video telephony system of claim 20, wherein the software switch is further configured to forward the out-of-band signals to another software switch using a routing table so that the other software switch can identify the address, when the address cannot be identified.

22. The video telephony system of claim 21, wherein the software switch is further configured to request QoS signaling between the media gateway and the other media gateway associated with the intended set-top box once the address is identified.

23. The video telephony system of claim 1, wherein the media gateway is further configured to receive the in-band and out-of-band signals rom the set-top bax, separate the in-band signals form the out-of-band signals, and route the out-of-band signals to the software switch.

24. The video telephony system of claim 23, wherein the media gateway is further configured to route the out-of-band signals to the software switch using splicing.

25. The video telephony system of claim 1, wherein the media gateway is configured to receive in-band signals from a plurality of set-top boxes, and wherein the video telephony system is configured to implement a dedicated spectrum allocation for the in-band signals associated with each of the plurality of set-top boxes.

26. The video telephony system of claim 1, wherein the media gateway is configured to receive in-band signals from a plurality of set-top boxes, and wherein the video telephony system is configured to implement a dynamic spectrum allocation for the in-band signals associated with each of the plurality of set-top boxes.

27. The video telephony system of claim 1, wherein the media gateway comprises logic configured to execute an open API middleware.

28. The video telephony system of claim 1, wherein the media gateway is configured to implement at least one enhanced service.

29. The video telephony system of claim 1, wherein the in-band signals comprise a plurality of media signals intended for a plurality of other set-top boxes associated with another media gateway, and wherein the media gateway is configured to splice the media signals together into one data stream and forward the data stream to the other media gateway.

30. The video telephony system of claim 1, wherein the out-of-band signals comprise a plurality of call setup signals and wherein the media gateway is configured to splice the plurality of call setup signals together and forward the spliced call setup signals to the software switch.

31. The video telephony system of claim 1, wherein the software switch is configured to control the media gateway, and wherein the media gateway is configured to handle the in-band signals under the control of the software switch.

32. The video telephony system of claim 1, wherein the media gateway is further configured to receive in-band signals form another media gateway and to forward the received in-band signals to the set-top box.

33. The video telephony system of claim 17, wherein the set-top box comprises a cable modem, and wherein the video telephony system further comprises a cable modem termination system configured to receive the in-band signals from the set-top box and forward them to the media gateway.

34. The video telephony system of claim 33, wherein the cable modem termination system is further configured to receive video call data from media gateway and forward it through a network interface to another media gateway.

35. The video telephony system of claim 34, wherein the cable modem termination system is further configured to combine the video call data with other data into a combined data stream and then to forward the combined data stream through the network interface.

36. The video telephony system of claim 35, wherein the other data includes at least one of Internet data and regular video broadcast data.

37. The video telephony system of claim 35, wherein the cable modem termination system is further configured to receive a combined data stream through a network interface and to separate the combined data stream into in-band data signals and other data signals.

38. The video telephony system of claim 37, wherein the cable modem termination system is further configured to forward the separated in-band signals to the media gateway and to forward at least some of the other data signals to the set-top box.

39. A method for video telephony communications, comprising:
receiving in-band and out-of-band signals;
separating the in-band form the out-of-band signals;
handling the in-band signals; and
forwarding the out-of-band signals to a software switch to be handled.

40. The method for claim 39, further comprising receiving commands from the software switch and handling the in-band signals according to the received instructions.

41. The method of claim 39, wherein handling the in-band signals comprises splicing the in-band signals into one media stream and forwarding the media stream to appropriate media gateways.

42. The method of claim 39, wherein forwarding the out-of-band signals comprises splicing the out-of-band signals into one combined call signaling stream and forwarding the combined call signaling stream to the software switch.

43. The method of claim 39, further compassion:
receiving the forwarded out-of-band signals;
determining a destination address based on the out-of-band signals; and
establishing a connection with a media gateway associated with the destination address.
